(19) United States
(12) Patent Application Publication
(10) Pub. No.: US 2009/0170331 A1
(43) Pub. Date: Jul. 2, 2009

(54) METHOD OF FORMING A BOTTLE-SHAPED TRENCH BY ION IMPLANTATION

(75) Inventors: Kangguo Cheng, Guilderland, NY (US); Johnathan E. Faltermeier, Delanson, NY (US); Carl Radens, Lagrangeville, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 12/187,917

(22) Filed: Aug. 7, 2008

Related U.S. Application Data
(63) Continuation of application No. 11/965,399, filed on Dec. 27, 2007, now abandoned.

(51) Int. Cl. H01L 21/3065

(52) U.S. Cl. 438/705; 257/E21.218

(57) ABSTRACT

Disclosed is a method of forming a bottle shaped trench in a substrate which includes forming at least one trench having an upper portion and a lower portion into a semiconductor substrate, the at least one trench having vertical sidewalls that extend to a common bottom wall; implanting ions into the semiconductor substrate abutting the upper portion of the at least one trench to form an amorphous region in the semiconductor substrate abutting the upper portion of the at least one trench; and etching the lower portion of the at least one trench selective to the amorphous region to provide an elongated bottom portion which extends laterally beyond the upper portion.

### RELATED APPLICATION

This application is a continuation of U.S. Ser. No. 11/965,399, filed Dec. 27, 2007

### FIELD OF THE INVENTION

The present invention generally relates to the fabrication of semiconductor devices, and more particularly, to a method of forming a bottle shaped trench in a substrate by ion implantation wherein trench capacitance is enhanced.

### DESCRIPTION OF THE PRIOR ART

A bottle shaped trench has been proposed as a method of increasing the storage capacitance in a semiconductor device. As used herein, the term “bottle shaped trench” denotes a trench having an upper and lower portion wherein the lower portion is elongated relative to the upper portion. Bottled shaped trenches are typically used to form a trench capacitor in an integrated circuit (IC). Some examples of ICs containing trench capacitors located in a bottle shaped trench include, for example, a random access memory (RAM), a dynamic random access memory (DRAM), a synchronous DRAM (SDRAM), and a read only memory (ROM). Other ICs such as an application specific IC (ASIC), a merged DRAM-logic circuit (embedded DRAM), or any other logic circuit can also include a trench capacitor within a bottle shaped trench.

There are several examples of conventional bottle shape trench fabrication methods, where for example, a bottle shaped trench is formed by covering the sidewalls of the substrate with a protective oxide and nitride layer to form a collar and to allow the formation of a tapered expanded base of a trench as discussed in U.S. Pat. No. 6,190,988 issued to Furukawa et al. Another similar example is forming a sacrificial etching layer in the bottle trench as discussed in U.S. Pat. No. 6,815,356 issued to Tsai et al., or forming multiple disposable protection layers in order to form a collar as discussed in U.S. Pat. No. 6,232,171 issued to Len Mei. Alternatively, a bottle shaped trench can be formed by filling the bottom portion of a trench with a shield material as discussed in U.S. Patent Application Publication No. 2003/0148580 applied by Chen et al.

The aforementioned conventional methods of fabricating a bottle shaped trench have the disadvantage in that forming a protection, sacrificial or disposable layer, or providing a filler material increases the complexity of the fabrication process by adding processing costs, introducing defects into the substrate and/or adding difficulty in process control. Moreover, the boundaries between the lower and upper portions of the bottle shaped trench are not well defined in the prior art. Hence, it would be desirable to have a method of forming a bottle shaped trench that is less complex and provides an improved boundary definition between a lower and upper portion of a trench.

Having set forth the limitations of the prior art, it is clear that what is required is a method of forming a bottle shaped trench in a substrate where trench capacitance can be improved by overcoming the structural limitations in forming a bottle shaped trench in conventional methods.

### SUMMARY OF THE INVENTION

The present invention provides a method for forming a bottle shaped trench in a substrate by ion implantation wherein trench capacitance is enhanced.

Specifically, the present invention provides a method of forming a bottle shaped trench in a substrate which comprises forming at least one trench having an upper portion and a lower portion into a semiconductor substrate, said at least one trench having vertical sidewalls that extend to a common bottom wall; implanting ions into said semiconductor substrate abutting the upper portion of said at least one trench to form an amorphous region in the semiconductor substrate abutting said upper portion of said at least one trench; and etching said lower portion of said at least one trench selective to the amorphous region to provide an elongated bottom portion which extends laterally beyond said upper portion.

In one embodiment of the present invention, ions are implanted into the semiconductor substrate abutting the upper portion of the trench by utilizing an angled ion implantation process.

In another embodiment of the present invention, ions are implanted into the semiconductor abutting the upper portion of the trench at an angle that is perpendicular to the semiconductor substrate.

In yet another embodiment of the present invention, the semiconductor substrate abutting the lower portion of the trench remains a single crystal material after the step of implanting ions.

In a further embodiment of the present invention, the method further comprises annealing said amorphous region abutting the upper portion of the semiconductor substrate at a temperature sufficient to recrystallize said amorphous region of said semiconductor substrate.

In another aspect of the present invention, a method of forming a bottle shaped trench is provided wherein an upper surface of the semiconductor substrate is implanted with ions rendering the upper surface amorphous prior to the step of forming a trench in said substrate. After forming the trench, the selective etching step mentioned above is performed to form a bottle shaped trench.

### BRIEF DESCRIPTION OF THE DRAWINGS

The objects, features and advantages of the present invention will become apparent to one skilled in the art, in view of the following detailed description taken in combination with the attached drawings, in which:

FIG. 1A is a pictorial representation of forming a deep trench in a semiconductor substrate material including a pad layer;

FIG. 1B is a pictorial representation of implanting ions at a predetermined angle in the upper sidewalls of a trench employed in a first embodiment of the present invention;

FIG. 1C is a pictorial representation of etching the lower portion of a deep trench employed in the first embodiment of the present invention;

FIG. 1D is a pictorial representation of thermal annealing the upper portion of trench employed in an optional step of the first embodiment of the present invention;

FIG. 2A is a pictorial representation of forming a trench in a semiconductor substrate material including a pad layer, a SOI substrate layer and a buried insulating layer;

FIG. 2B is a pictorial representation of implanting ions at a predetermined angle in the upper sidewalls of a deep trench located in a SOI substrate employed in a second embodiment of the present invention;

FIG. 2C is a pictorial representation of etching the lower portion of a trench employed in the second embodiment of the present invention;

FIG. 2D is a pictorial representation of thermal annealing the upper portion of the trench employed in an optional step of the second embodiment of the present invention;

FIG. 3A is a pictorial representation of implanting ions perpendicular to the upper sidewalls of a trench employed in a third embodiment of the present invention;

FIG. 3B is a pictorial representation of etching the lower portion of a trench employed in the third embodiment of the present invention;

FIG. 3C is a pictorial representation of thermal annealing the upper portion of the trench employed in an optional step of the third embodiment of the present invention;

FIG. 4A is a pictorial representation of implanting ions perpendicular to a pad layer employed in a fourth embodiment of the present invention;

FIG. 4B is a pictorial representation of forming a deep trench extending into the amorphous region of the substrate and continuing down into a non-amorphous lower portion of the substrate in the fourth embodiment of the present invention;

FIG. 4C is a pictorial representation of etching the lower portion of a trench employed in the fourth embodiment of the present invention; and

FIG. 4D is a pictorial representation of thermal annealing the upper portion of the trench employed in an optional step of the fourth embodiment of the present invention.

### DETAILED DESCRIPTION OF THE PREFERRED EMBODIMENTS

Hereinafter, embodiments of the present invention will be described in detail with reference to the accompanying drawings. For the purposes of clarity and simplicity, a detailed description of known functions and configurations incorporated herein will be omitted as it may make the subject matter of the present invention unclear. It is noted that the inventive method can be used in forming a plurality of bottle shaped trenches within a semiconductor substrate. The bottled shaped trenches can then be processed using conventional techniques to form at least a capacitor device or other semiconductor device within the bottle shaped trenches.

As stated above, the present invention provides a method for forming a bottle shaped trench in a semiconductor substrate by ion implantation wherein trench capacitance is enhanced. Ion implantation, as employed in the present invention, relates to a process by which ions of a first material are implanted into a second material at a predetermined energy level, which changes the physical properties of the second material. Accordingly, introducing ions of a first material into a second material introduces both a chemical charge in the targeted second material and a structural change in the crystal structure of the targeted second material.

In accordance with the first embodiment of the present invention, the following steps form a bottle shaped trench in a semiconductor substrate by ion implantation wherein trench capacitance is enhanced: a) forming a deep trench in a semiconductor substrate; b) amorphizing the semiconductor substrate abutting an upper portion of the deep trench by an angled ion implantation method; and c) etching the semiconductor substrate abutting a lower portion of the trench to widen the lower portion of the trench with respect to the upper trench. That is, the etching step is performed selective to the amorphous region to provide an elongated bottom portion which extends laterally beyond the upper portion. Hereafter a detailed explanation of the method of forming a bottle shaped trench in accordance with the first embodiment of the present invention is provided.

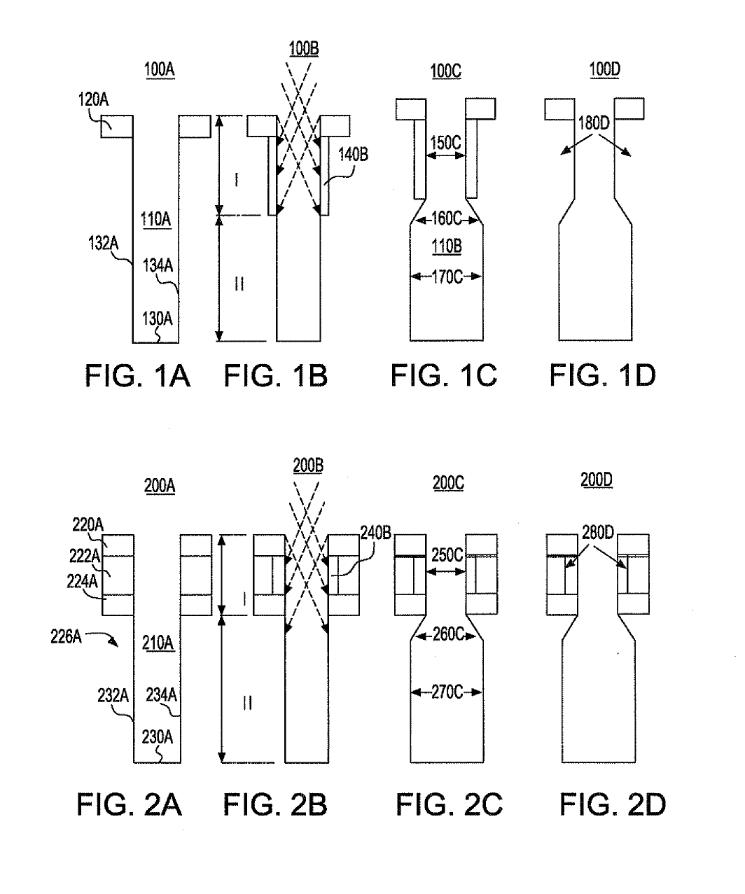

Referring to FIG. 1A, a pictorial representation of forming a trench in a semiconductor substrate including a pad layer deposited thereon is shown. The process of forming a trench is conventional and includes providing a semiconductor substrate material 100A, such as silicon, gallium arsenide, germanium, or other semiconductor materials as known by those skilled in the art with a pad layer 120A, such as, silicon nitride and/or silicon oxide deposited and/or thermally grown thereon. Thereafter, a trench 110A is formed having vertical sidewalls 132A and 132B that extend to a common bottom wall (or base) 130A by patterning and etching. The patterning step includes applying one or more masking layers (not shown) to the upper surface of the pad layer 120A, and patterning the masking material(s) by lithography as well as etching, if needed. The pattern in the masking layer(s) is then transferred to the pad layer 120A and the substrate 100A to form the trench by etching. The etching step includes a dry etching process such as, for example, reactive ion etching, plasma etching, and ion beam etching, and/or a chemical wet etching process. Typically reactive ion etching is employed. The etching step may include first transferring the trench pattern from the masking layer(s) to the pad layer 120A, and then etching is continued to transfer the trench pattern into the semiconductor substrate. In the case that the masking layer(s) comprise a photoresist, the photoresist is typically removed utilizing a conventional resist stripping process such as ashing.

The depth of the trench 110A may vary depending on the technique used in forming the same as well as the type of device that will be subsequently formed therein. Typically, the trench 110A has a depth, as measured from the upper surface of the substrate 100A to the common bottom wall 130A of the trench 110A, from about 1 to about 10 micron meters, although lesser and greater trench depth is also explicitly contemplated herein.

After formation of the trench 110A into the semiconductor substrate 100A, the semiconductor substrate 100A abutting an upper portion of the trench (designated as I in FIG. 1B; the lower portion of the trench is designated as II) is rendered amorphous by an angled ion implantation method as shown in to FIG. 1B. As can be seen in FIG. 1B, ions, depicted as arrows are implanted at a predetermined angle through the upper sidewalls of the trench 110A into the abutting semiconductor substrate. In FIG. 1B, reference number 140B denotes the amorphous regions that are formed after performing the ion implantation step.

The implanted ions in accordance with the first embodiment of the present invention can be any ion that is capable of rendering the semiconductor substrate amorphous. Examples of such amorphizing ions include, but are not limited to, argon, krypton, neon, helium, boron, indium, thallium, carbon, silicon, germanium, nitrogen, phosphorus, arsenic, sulfur, iodine, oxygen, boron fluoride, or any combination of these ions. To render the substrate abutting the upper portion of the trench amorphous in accordance with one possible embodiment of the present invention requires ion energy levels, depending on the implanted ions and the implantation angle, within a range from about 2 to about 800 keV. A preferred range is from about 10 to about 200 keV and a most preferred range is from about 30 to about 60 keV. The dose of the amorphizing ions being implanted may vary depending on the type of amorphized ion being implanted. Typically, the dose of the implanted amorphizing ion is from about 1×10¹⁷ to about 1×10²¹ atoms/cm², with a dose from about 2×10¹⁸ to about 1×10¹⁹ atoms/cm² being even more typical. The implantation angle, which is defined as the angle between the ion beam and the sidewall of the trench, ranges from about 0.1 degree to 89.5 degree. A preferred range of implantation angle is from about 5 to about 60 degree and a most preferred range of the implantation angle is from about 15 to about 30 degree.

After the substrate abutting the upper portion I of the trench 110A is rendered amorphous, the substrate abutting the lower portion II of the trench 110A is subjected to an etching step which widens the lower portion II of the trench 110C with respect to the upper portion as shown in FIG. 1C. That is, the etching step is performed selective to the amorphous region to provide an elongated bottom portion that extends laterally beyond the upper portion. In accordance with the first embodiment of the present invention, a desired geometric bottle shaped deep trench is formed by widening the lower portion II of the trench at predetermined distance 170C, and forming a tapered collar 160C while the distance between the upper portion of the trench 150C remains unchanged. The etching step includes any etching process that is capable of elongating a lower portion of the trench relative to the upper portion of the trench. The etch step is performed selective to the amorphous region 140B and can include any suitable etching process, such as, for example, a wet etch process with an etchant containing ammonium hydroxide (NH₄OH), potassium hydroxide (KOH), tetramethylammonium hydroxide (TMAH), hydrazine, ethylene diamine pyrocatechol (EDP), or a mix of hydrofluoric acid and nitric acid. In a particular embodiment, an etchant comprising a 50:1 concentration of H₂O:NH₄OH is performed at 25° C. to enlarge the lower portion of the trench without substantially etching the upper portion of the trench.

In one embodiment of the present invention, the predetermined distance of upper portion of the trench 150C is from about 5 nm to about 500 nm, while the predetermined distance of the lower portion of the trench 170C is about 5 nm to about 100 nm greater than the distance of the upper portion of the trench 150C. Another possible embodiment of the present invention can provide the predetermined distance of the lower portion of the trench 170C from about 50 nm to about 150 nm, while a more preferable embodiment would require that the predetermined distance of the lower portion of the trench 170C is about 80 nm to 120 nm. However, those skilled in the art would know that depending on the specific application (e.g., RAM, DRAM, SDRAM or ROM, etc), that the actual dimensions of a bottle shaped trench might vary to accommodate a specific application. Accordingly, the etching step as described in this application is not limiting.

After etching the trench to form the desired geometric bottle shaped, an optional step of thermal annealing may be employed in the first embodiment of the present invention as shown in FIG. 1D. I FIG. 1D, reference numeral 180D refers to a re-crystallized region. Certain applications, such as DRAM, may require that the upper portion I of the trench be re-crystallized into a single crystal material. After re-crystallization, the previously rendered amorphous region has the same crystal structure as the semiconductor substrate that abuts the lower portion II of the trench. To restore the amorphous semiconductor substrate in the upper portion I of the trench to a single crystal structure, the structure is subjected to a recrystallizing anneal that is performed at a temperature from about 500° C. to about 1200° C. A preferred temperature for the re-crystallizing anneal is from about 600° C. to about 900° C. and a most preferred annealing temperature is about 800° C. The re-crystallizing annealing is typically performed in an inert ambient such as, for example, N₂, He and/or Ar.

In accordance with a second embodiment of the present invention, the above steps described in reference to the first embodiment are employed in forming a bottle shaped trench in a semiconductor substrate by ion implantation wherein trench capacitance is enhanced. As shown in FIG. 2A, a trench 210A is formed into a semiconductor-on-insulator (SOI) substrate 200A that includes a pad layer 220A thereon utilizing the same basic processing steps as described above in regard to forming the structure shown in FIG. 1A. In FIG. 2A, reference numeral 232A and 232B denote trench sidewalls and reference numeral 230A denotes the trench bottom wall. The SOI substrate includes a handle substrate 226A, a buried insulating layer, such as a buried oxide, 224A located on a surface of the handle substrate 226A, and a top semiconductor layer, i.e., an SOI layer, 222A located on the buried insulating layer. Typically, the handle substrate 226A and the top semiconductor layer 222A are comprised of a semiconductor such as, for example, Si, Ge, SiGe, or any other suitable semiconductor materials.

After the trench is formed, in accordance with the second embodiment of the present invention, the SOI layer is subjected to an angular ion implantation as depicted by the arrows in FIG. 2B. Only the sidewalls 240B of the SOI layer 222A become amorphous. As discussed above, in reference to the first embodiment, the lower portion II of the trench is etched to a desired geometric bottle shaped deep trench 210C formed by widening the lower portion of the trench II at predetermined distance 270C, and forming a tapered collar 260C at a predetermined distance while the distance between the upper portion of the trench 250C remains unchanged. See, FIG. 2C.

After etching the trench to form the desired geometric bottle shaped, an optional step of thermal annealing may be employed in the second embodiment of the present invention as shown in FIG. 2D. The optional thermal anneal used in the second embodiment are the same as described above. In FIG. 2D, reference numeral 280D denotes the re-crystallized regions that are formed after performing this annealing step.

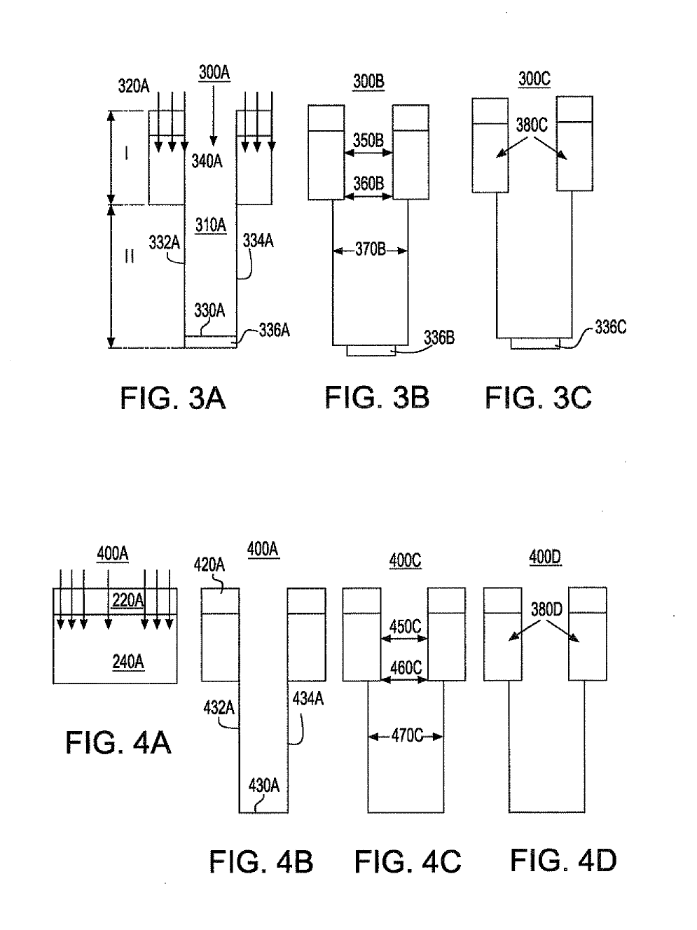

In accordance with the third embodiment of the present invention, the above steps, described in reference to the first embodiment are again employed in forming a bottle shaped trench in a semiconductor substrate 300A by ion implantation wherein trench capacitance is enhanced. As shown in FIG. 3A, the prior art of forming a trench 310A including trench sidewalls 332A and 332B and bottom wall 330A, as discussed above is again utilized to form a desired geometric deep trench.

After formation of the trench, in accordance with the third embodiment of the present invention, the semiconductor substrate abutting an upper portion of the trench (designated as I in FIG. 3A; the lower portion of the trench is designated as II) is subjected to ion implantation as depicted by the arrows in FIG. 3A. However, unlike the first and second embodiments, discussed above, the ion beam is perpendicular to the surface of the substrate 300A, or virtually parallel to sidewalls 332A and 334A. As can be seen in FIG. 3A, a larger cross section of the upper portion of the trenched substrate is amorphized, as compared to the previous embodiments. In addition, the bottom of the trench 330A becomes amorphous due to the orientation of the ions forming an amorphous base 336A.

As discussed above, in reference to the first embodiment, the lower portion II of the trench substrate is etched to a desired geometric bottle shaped deep trench 310B formed by widening the lower portion of the trench substrate II at predetermined distance 370B, and while the distance between the upper portion of the trench 350B remains unchanged. However, as can be seen in FIG. 3B, a tapered collar is not formed in the third embodiment of the present invention. Instead, this embodiment provides an improved boundary definition 360B between a lower portion I and upper portion II of the trench substrate to further enhanced trench capacitance. Thereafter, the amorphous base 336B may optionally be removed and discarded by an etching method, such as reactive ion etching or plasma etching, however, the actual etching method is not limiting, and may be replaced by any method known to those skilled in the art to perform a mask open etch to form.

An optional thermal anneal step may be employed with respect to the third embodiment as discussed above. Particularly, an optional thermal anneal step can be performed to the upper portion I of the trench to re-crystallize that portion into a single crystal as shown in FIG. 3C. Again, the amorphous base 336B may optionally be removed and discarded by an etching method, as discussed above. In FIG. 3C, reference numeral 380D denotes the re-crystallized region and reference numeral 336C denotes a re-crystallized base.

In accordance with a fourth embodiment of the present invention, the above steps, described in reference to the first embodiment are again employed in forming a bottle shaped trench in a semiconductor substrate by ion implantation wherein trench capacitance is enhanced. However, as shown in FIG. 4A-4C, the sequence of the steps are rearranged. The beam of ions to be implanted as depicted by the arrows in FIG. 4A are perpendicular to the surface area of the substrate 440A and pad layer 420A. In the fourth embodiment, the substrate is first implanted with ions as shown in FIG. 4A, and then a trench is formed as shown in FIG. 4B and discussed above in reference to the prior art in FIG. 1A having trench sidewalls 432A and 432B and bottom wall 430A. Then, as discussed above in reference to the third embodiment and FIG. 3B, the geometric shape of the bottle shape trench 410C is etched with improved boundary definition 460C between a lower portion I and upper portion II of the trench 410C. In FIG. 4C, reference numeral 450C denotes the distance between the sidewalls of the upper portion of the trench and 470C denotes the distance between the sidewalls of the lower portion of the trench. This embodiment of the present invention has the benefit of not requiring the removal of an amorphous base as optionally required in the third embodiment, since no amorphous base is formed.

An optional thermal annealing step may be employed with respect to this embodiment as well. The process of thermal annealing to the upper portion I of the trench 480D re-crystallizes that portion into a single crystal material as shown in FIG. 4D.

As disclosed herein, the aforementioned embodiments provide multiple methods of fabricating a bottle shaped trench having the advantage over convention methods in that there is no need to form a protection, sacrificial or disposable layer, or providing a filler material thus decreasing the complexity of the fabrication process by reducing processing costs, and reducing the introduction of defect into the geometric shapes of the bottle shape trench, and provides for an easier process to control. Moreover, the boundaries between the lower and upper portions of the conical shaped trench are well defined.

While there has been shown and described what is considered to be preferred embodiments of the invention, it will, of course, be understood that various modifications and changes in form or detail could readily be made without departing from the spirit of the invention. It is therefore intended that the scope of the invention not be limited to the exact forms described and illustrated, but should be construed to cover all modifications that may fall within the scope of the appended claims.

What is claimed is:

1. A method of forming a bottle shaped trench in a substrate, comprising:
forming at least one trench having an upper portion and a lower portion into a semiconductor substrate, said at least one trench having bare vertical sidewalls that extend to a common bottom wall;
implanting ions into said semiconductor substrate abutting the upper portion of said at least one trench to form an amorphous region in the semiconductor substrate abutting said upper portion of said at least one trench; and
etching said lower portion of said at least one trench selective to the amorphous region to provide an elongated bottom portion which extends laterally beyond said upper portion, wherein the semiconductor substrate abutting the lower portion of the trench remains a single crystal material.

2. The method of claim 1, further comprising:
annealing said amorphous region abutting the upper portion of the semiconductor substrate, at a temperature sufficient to recrystallize said amorphous region of said substrate.

3. The method of claim 1 wherein said implanting ions is performed using an angled ion implantation in which the angle between the ion beam and bare vertical sidewalls is from about 0.1 to 89.5 degrees.

4. The method of claim 3 wherein said implanting ions is performed at an energy from about 2 to about 800 keV using an ion dose of from about 2×10¹⁸ to about 1×10¹⁹ atoms/cm².

5. The method of claim 1 wherein said implanting ions includes selected at least one of argon, krypton, neon, helium, boron, indium, thallium, carbon, silicon, germanium, nitrogen, phosphorus, arsenic, sulfur, iodine, oxygen and boron fluoride.

6. The method of claim 1 wherein said etching includes a wet etch process including an etchant selected from ammonium hydroxide (NH₄OH), potassium hydroxide (KOH), tetramethylammonium hydroxide (TMAH), hydrazine, ethylene diamine pyrocatechol (EDP) and or a mix of hydrofluoric acid and nitric acid.

7. The method of claim 6 wherein said etchant comprising a 50:1 concentration of H₂O:NH₄OH and said etching is performed at 25° C. to enlarge the lower portion of the trench without substantially etching the upper portion of the trench.

8. The method of claim 2 wherein said annealing is performed at a temperature from about 500° C. to about 1200° C. and in an inert gas ambient.

9. The method of claim 1 wherein said semiconductor substrate is a bulk semiconductor.

10. The method of claim 1 wherein said semiconductor substrate is a semiconductor-on-insulator.

11. The method of claim 1 wherein said implanting ions is performed using an ion implantation in which the angle between the ion beam and bare vertical sidewalls is 0 degrees thereby further forming an amorphous region beneath the common wall portion.

12. A method of forming a bottle shaped trench in a substrate, comprising:
implanting ions into said semiconductor substrate to render an upper surface thereof amorphous;
forming at least one trench having an upper amorphous region and a lower portion into a semiconductor substrate, said at least one trench having bare vertical sidewalls that extend to a common bottom wall; and
etching said lower portion of said at least one trench selective to the amorphous region to provide an elongated bottom portion which extends laterally beyond said upper portion, wherein the semiconductor substrate abutting the lower portion of the trench remains a single crystal material.

13. A method of forming a bottle shaped trench in a substrate, said method consisting essentially of:
forming at least one trench having an upper portion and a lower portion into a semiconductor substrate, said at least one trench having bare vertical sidewalls that extend to a common bottom wall;
implanting ions into said semiconductor substrate abutting the upper portion of said at least one trench to form an amorphous region in the semiconductor substrate abutting said upper portion of said at least one trench; and
etching said lower portion of said at least one trench selective to the amorphous region to provide an elongated bottom portion which extends laterally beyond said upper portion, wherein the semiconductor substrate abutting the lower portion of the trench remains a single crystal material.

14. The method of claim 13, further comprising:
annealing said amorphous region abutting the upper portion of the semiconductor substrate, at a temperature sufficient to recrystallize said amorphous region of said substrate.

15. The method of claim 13 wherein said implanting ions is performed using an angled ion implantation in which the angle between the ion beam and bare vertical sidewalls is from about 0.1 to 89.5 degrees.

16. The method of claim 15 wherein said implanting ions is performed at an energy from about 2 to about 800 keV using an ion dose of from about 2×10¹⁸ to about 1×10¹⁹ atoms/cm².

17. The method of claim 13 wherein said implanting ions includes selected at least one of argon, krypton, neon, helium, boron, indium, thallium, carbon, silicon, germanium, nitrogen, phosphorus, arsenic, sulfur, iodine, oxygen and boron fluoride.

18. The method of claim 13 wherein said etching includes a wet etch process including an etchant selected from ammonium hydroxide (N₄OH), potassium hydroxide (KOH), tetramethylammonium hydroxide (TMAH), hydrazine, ethylene diamine pyrocatechol (EDP) and or a mix of hydrofluoric acid and nitric acid.

19. The method of claim 18 wherein said etchant comprising a 50:1 concentration of H₂O:NH₄OH and said etching is performed at 25° C. to enlarge the lower portion of the trench without substantially etching the upper portion of the trench.

20. The method of claim 13 wherein said implanting ions is performed using an ion implantation in which the angle between the ion beam and bare vertical sidewalls is 0 degrees thereby further forming an amorphous region beneath the common wall portion.
